(19) United States
(12) Patent Application Publication
(10) Pub. No.: US 2025/0357336 A1
(43) Pub. Date: Nov. 20, 2025

(54) SEMICONDUCTOR DEVICE WITH SEAL RING STRUCTURE AND METHOD MAKING THE SAME

(71) Applicant: Taiwan Semiconductor Manufacturing Company, Ltd., Hsinchu (TW)

(72) Inventors: Wen-Chiung Tu, New Taipei City (TW); Hsiang-Ku Shen, Hsinchu City (TW); Chen-Chiu Huang, Taichung City (TW); Dian-Hau Chen, Hsinchu (TW); Shu Fang Chen, Hsinchu (TW)

(21) Appl. No.: 19/284,287

(22) Filed: Jul. 29, 2025

Related U.S. Application Data
(63) Continuation of application No. 18/513,325, filed on Nov. 17, 2023.
(60) Provisional application No. 63/515,874, filed on Jul. 27, 2023.

(51) Int. Cl. H01L 23/528; H01L 21/768; H01L 23/522; H01L 23/58

(52) U.S. Cl. CPC H01L 23/528; H01L 21/768; H01L 23/5226; H01L 23/585

(57) ABSTRACT

A semiconductor structure that includes a substrate having a circuit region and a seal ring region around the circuit region. The seal ring region includes a multi-layer interconnect to form a seal ring structure. And a redistribution layer is formed over the seal ring structure. The redistribution layer is formed on the edges of the seal ring region, and excluded from corner regions of the seal ring.

### CROSS-REFERENCE TO RELATED APPLICATIONS

This application is a continuation of U.S. patent application Ser. No. 18/513,325 filed Nov. 17, 2023, which claims priority to U.S. Prov. App. Ser. No. 63/515,874, filed Jul. 27, 2023, the entire disclosures of which are incorporated herein by reference.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This sealing down process generally provides benefits by increasing production efficiency and lowering associated costs. Such sealing down has also increased the complexity of processing and manufacturing ICs.

In semiconductor technologies, a semiconductor substrate such as a wafer is processed through various fabrication steps to form ICs. Typically, several circuits or IC dies are formed onto the same semiconductor wafer. The wafer is then diced to separate the die for further packaging and system implementation. To protect the circuits from environmental conditions and/or dicing and packaging processes, a seal ring is formed around the circuit region of each die. Although existing seal rings and fabrication methods have been generally adequate for their intended purposes, improvements are desired.

### BRIEF DESCRIPTION OF THE DRAWINGS

The present disclosure is best understood from the following detailed description when read with the accompanying figures. It is emphasized that, in accordance with the standard practice in the industry, various features are not drawn to scale and are used for illustration purposes only. In fact, the dimensions of the various features may be arbitrarily increased or reduced for clarity of discussion.

FIG. 1A is a top plan view of a semiconductor structure according to the present disclosure.

FIG. 1B is a top plan view of a portion of the semiconductor structure of FIG. 1A according to aspects of the present disclosure.

FIG. 1C is a corresponding cross-sectional view of the semiconductor structure of FIG. 1A according to aspects of the present disclosure.

FIG. 2A is a top plan view of another semiconductor structure according to the present disclosure.

FIG. 2B is a top plan view of a portion of the semiconductor structure of FIG. 2A according to aspects of the present disclosure.

FIG. 2C is a corresponding cross-sectional view of the semiconductor structure of FIG. 2A according to aspects of the present disclosure.

FIG. 3 is a top view of an embodiment of a metallization layer according to aspects of the present disclosure.

FIG. 4 is a top plan view of another semiconductor structure according to aspects of the present disclosure.

FIG. 5 is a top plan view of another semiconductor structure according to aspects of the present disclosure.

FIG. 6A is a top view of a semiconductor structure including a seal ring area and a circuit area according to aspects of the present disclosure.

FIG. 6B is a cross-sectional view of the semiconductor structure of FIG. 6A according to aspects of the present disclosure.

FIG. 7 is a flowchart of a method of making a semiconductor structure according to various aspects of the present disclosure.

FIGS. 8A, 8B, 8C and 8D are cross-sectional views corresponding to certain stages of the method of FIG. 7, according to various aspects of the present disclosure.

FIG. 9 is a flowchart of a method making a semiconductor structure having a capacitor according to aspects of the present disclosure.

FIGS. 10A, 10B, 10C, 10D, 10E, and 10F are cross-sectional views corresponding to certain stages of the method of FIG. 9, according to aspects of the present disclosure.

FIG. 11 is a flowchart of a method of designing and fabricating a semiconductor structure according to aspects of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. Still further, when a number or a range of numbers is described with “about,” “approximate,” and the like, the term encompasses numbers that are within certain variations (such as +/−10% or other variations) of the number described, in accordance with the knowledge of the skilled in the art in view of the specific technology disclosed herein, unless otherwise specified. For example, the term “about 5 nm” may encompass the dimension range from 4.5 nm to 5.5 nm, 4.0 nm to 5.0 nm, etc.

A semiconductor device, such as an integrated circuit die (also referred to as a chip), includes a circuit region surrounded by a seal ring region. In the circuit region, various passive and active semiconductor devices, such as resistors, capacitors, inductors, diodes, p-type FETs (PFETs), n-type FETs (NFETs), metal-oxide semiconductor FETs (MOSFETs), complementary metal-oxide semiconductor (CMOS) transistors, bipolar junction transistors (BJTs), laterally diffused MOS (LDMOS) transistors, high voltage transistors, high frequency transistors, other components, or a combination thereof are formed. In an embodiment, the circuit region includes at least one transistor. The semiconductor devices may be interconnected such as by multi-layer interconnect (MLI) structures to form ICs.

The seal ring region surrounds the circuit region and provides protection to the devices in the circuit region. The seal ring region includes seal ring structures that provide the devices, and thus the ICs, from environmental conditions moisture degradation, ionic contamination, and/or damage during processing such as, damage during dicing processes of the wafer. For example, moisture entering the circuits can impact dielectric and metallization quality and thus, device performance. Ionic contaminants can also cause damage to the IC for instance creating risk of threshold voltage instability in devices (e.g., transistors) and altering the surface potential of the semiconductor surfaces. Dicing processes of the semiconductor wafer that separate adjacent IC dies from one another may also cause potential damage.

To provide this protection, the seal ring region has a seal ring structure that is formed surrounding the circuit region of the die. The seal ring structure may extend upward from the substrate in a vertical direction, and surround the circuit region from a top view. The seal ring structure may be formed during (e.g., concurrently with) fabrication of the many layers that form the semiconductor devices, including both the front-end-of-line (FEOL) processing, the middle-end-of-line (MEOL) structures, or back-end-of-line processing (BEOL). FEOL structures include structural features of transistors or other semiconductor devices fabricated on a semiconductor substrate such as gate structures, source/drain features and the like; MEOL structures include contact structures such as source/drain contact vias or gate contact vias; and BEOL structure include interconnect structures such as multi-layer interconnects (MLI) of metal lines and vias, and passivation structures over the MLI. In particular, in the present illustrations, the seal ring structure includes BEOL features of the MLI. The seal ring structure provides protection of the IC from environmental effects and processing risks discussed above as it in effect creates a wall or walls surrounding the circuit region.

In some implementations, the seal ring structures do not provide electrical functions but serve to enclose and protect the circuit area from moisture, mechanical stress, or other defect-generating mechanism as discussed above. In other implementations, in addition to one or more of these functions, the seal ring structure may be connected to or coupled to a ground (or ground terminal or potential). The seal ring structure, while it may be connected to ground, may not be interconnected to devices of the circuit region from an electrical standpoint.

As discussed above, a die or chip includes a circuit region and a seal ring region surrounding the circuit region. The seal ring region may be a polygon shape, illustrated in some embodiments herein as a rectangular shape; however, any shape is possible. In some implementations, the seal ring region extends to an edge of the substrate or die. In some implementations, outside of the seal ring region, a scribe line region of the wafer may be disposed. The scribe line region may be a region originally fabricated in the scribe lines (saw streets, etc.) between die on the wafer, and left with the die after singulation. In some embodiments, no functional structures are disposed in the scribe line region.

In some embodiments, the seal ring region includes various sub-regions. The sub-regions include [1] a scribe line dummy (SLD) region or scribe line dummy bar (SLDB) region, [2] a seal ring wall (SR) region, and [3] a seal ring enhanced zone (SREZ) region. The orientation of the sub-regions is disposed from a circuit region to an edge of the die in a SLD/SLDB, SR, and SREZ orientation. Other subregions or omission of a subregion may also be possible. In some implementations, after singulation, the SLD/SLDB region is at the periphery of the die the remaining of the scribe line region being removed in the dicing process.

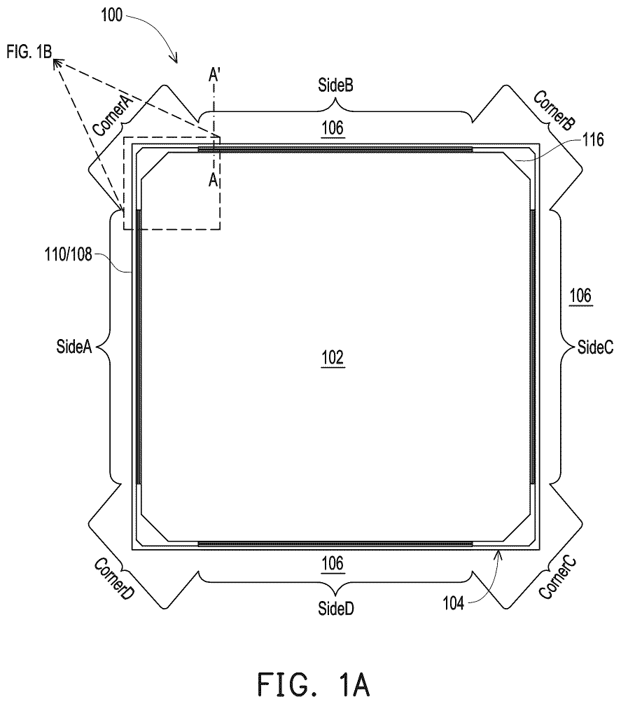

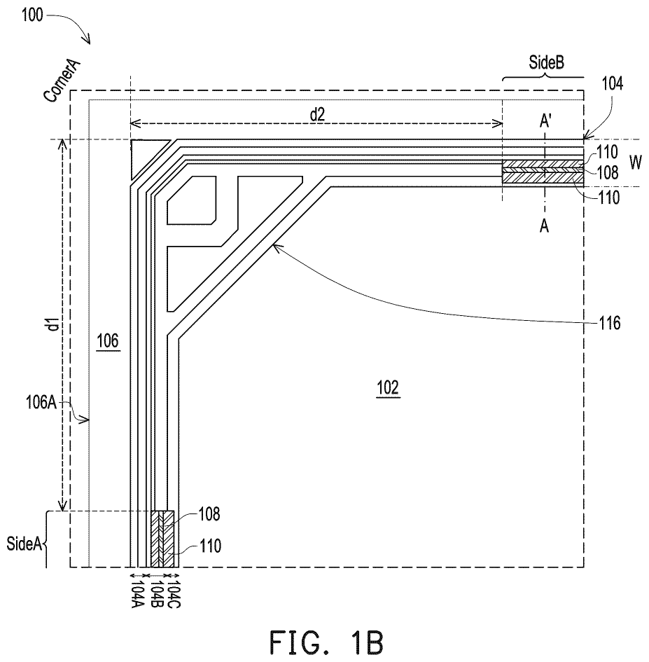

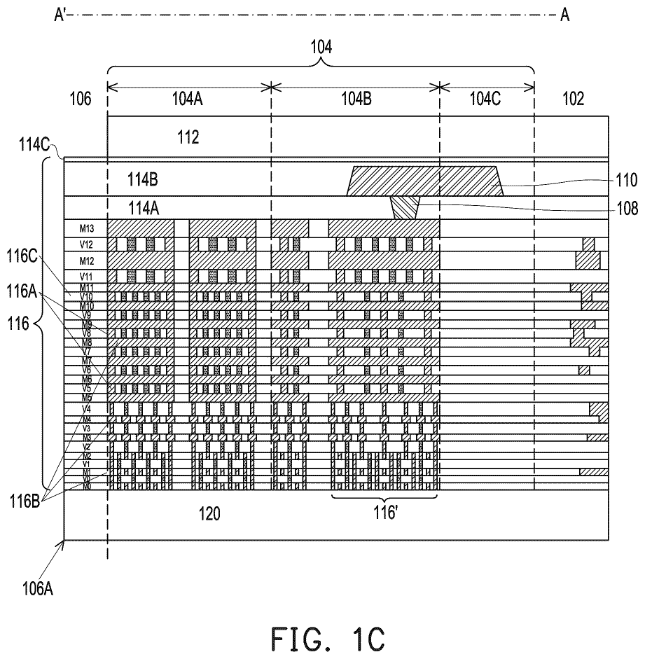

FIG. 1A is a top plan view of a semiconductor structure 100 according to aspects of the present disclosure. The semiconductor structure 100 (such as a manufactured wafer or a part thereof or a semiconductor die or portion thereof) includes a circuit region (or device region) 102 and a seal ring region 104 that encloses the circuit region 102 from a top view. The circuit region 102 may include a plurality of active and/or passive devices as discussed above. In an embodiment, the circuit region 102 includes at least one transistor. The seal ring region 104 is formed as a rectangular structure having four sides-labeled SideA, SideB, SideC, SideD and four corner regions-labeled CornerA, CornerB, CornerC, CornerD.

A seal ring structure 116 is disposed in the seal ring region 104. The seal ring structure 116 is a MLI disposed over a substrate and extending upward in a z-direction as discussed in detail below including with respect to FIG. 1C. The seal ring structure 116 from a top view as illustrated in FIG. 1, encases or encloses the circuit region 102 on all lateral sides (and corners). The seal ring structure 116 is continuous in the top view to provide for uninterrupted wall around the circuit region 102. FIG. 1B shows an inset of FIG. 1A at the CornerA region for ease of illustration. In some implementations, the seal ring region 104 extends a width w as measured in the top view. In an embodiment, the width w may be between approximately 13 microns (μm) and approximately 35 μm. In some implementations, the seal ring structure 116 extends a width w, as measured in the top view. In an embodiment, the width w may be between approximately 13 microns (μm) and approximately 35 μm. The CornerA region of the seal ring region 104 includes a first length d1 and a second length d2. In an embodiment, the first length d1 is between approximately 50 μm and approximately 200 μm. In an embodiment, d1 is at least 50 μm. In an embodiment, the second length d2 is between approximately 50 μm and approximately 200 μm. In an embodiment, d2 is at least 50 μm. As discussed below, the corner region, CornerA, includes the seal ring structure 116 but is devoid of a redistribution layer 110 over the seal ring structure 116.

As discussed above, the seal ring region 104 includes a plurality of subregions that form the seal ring region 104. As illustrated in FIG. 1B, the seal ring region 104 includes a first region 104A that is a SLDB/SLD region, a second region 104B that is a SR (seal ring wall), and a third region 104C that is a SREZ. In an embodiment, the first region 104A has a width of between 5 μm and approximately 10 μm in a top view (e.g., parallel the width w). In an embodiment, the second region 104B has a width of between 5 μm and approximately 15 μm in a top view. In an embodiment, the third region 104C has a width of between 3 μm and approximately 10 μm in a top view.

A scribe line region 106 is disposed outside of the seal ring region 104. In some embodiments, the scribe line region 106 extends to a seal ring region of an adjacent die when in wafer form. In some embodiments, the scribe line region 106 is a residual portion of the scribe line in wafer form maintained on the final chip (e.g., after dicing). That is, after separation of the die, an edge of the die 106A is provided. Thus, the scribe line region 106 provides an edge region of the die that may not include any functional devices.

As also illustrated in FIGS. 1A and 1B, a super redistribution layer (sRDL) 110 (also referred to as a redistribution layer) and a redistribution via (RV) 108 are disposed over the seal region structure 116 in the seal ring region 103. In particular, the sRDL 110 and the RV 108 are disposed in the second region 104B (e.g., SR). In an embodiment, the sRDL 110 extends into the third region 104C (e.g., SREZ). In some embodiments, neither sRDL 110 nor RV 108 are disposed in the third region 104C (e.g., SREZ).

The sRDL 110, and the RV 108, are disposed at the lateral sides of the seal ring region 104 in a top view. However, the sRDL 110 and the RV 108 are not disposed in the corner regions of the seal ring region 104. In some implementations, omissions of the sRDL 110 and/or the RV 108 from the corner regions (e.g., CornerA, CornerB, CornerC, and CornerD) serves to mitigate cracking of the protective layer(s) (e.g., passivation) and/or delamination of protective layers in the corner regions. As illustrated

by the example of FIG. 1B, the CornerA region of the seal ring region 104 includes the first length d1 and the second length d2 (e.g., approximately 50 μm and approximately 200 μm in some implementations) where there is no RDL component. That is there is a terminal end of the sRDL 110 in the top view that falls within the seal ring region 104. The sRDL 110 as illustrated in the top view of FIGS. 1A/1B is illustrative of a continuous line extending along each side (e.g., SideA, SideB, SideC, SideD). However, other configurations are possible including as illustrated below.

The RV 108 and the sRDL 110 may include copper. In other embodiments, the RV 108 and the sRDL 110 include other conductive materials such as aluminum, aluminum alloy (such as aluminum/silicon/copper alloy), copper alloy, titanium, titanium nitride, tantalum, tantalum nitride, tungsten, polysilicon, metal silicide, other suitable metals, or a combination thereof. The RV 108 and/or the sRDL 110 may include multiple layers such as a seed layer or adhesive layer.

FIG. 1C illustrates a corresponding cross-sectional view along line A-A′ of FIGS. 1A/1B and provides additional details of the structure 100. FIG. 1C illustrates a substrate 120 on which the circuit region 102, the seal ring region 104, and the scribe line region 106 are disposed.

The substrate 120 may include an elementary (single element) semiconductor, such as silicon (Si), germanium (Ge), and/or other suitable materials; a compound semiconductor (i.e., alloy semiconductor), such as silicon carbide (SiC), gallium arsenic (GaAs), gallium phosphide (GaP), indium phosphide (InP), indium arsenide (InAs), indium antimonide (InSb), silicon germanium (SiGe), gallium arsenic phosphide (GaAsP), aluminum indium arsenide (AlInAs), aluminum gallium arsenide (AlGaAs), gallium indium arsenide (GaInAs), gallium indium phosphide (GaInP), gallium indium arsenide phosphide (GaInAsP), and/or other suitable materials. The substrate 120 may be a single-layer material having a uniform composition. Alternatively, the substrate 120 may include multiple material layers having similar or different compositions suitable for IC device manufacturing. In one example, the substrate 120 may be a silicon-on-insulator (SOI) substrate having a silicon layer formed on a buried silicon oxide (BOX) layer. In some embodiments, the substrate 120 includes various doped regions, such as n-type wells or p-type wells. The doped regions may be doped with n-type dopants, such as phosphorus (P) or arsenic (As), and/or p-type dopants, such as boron (B) or BF₂, depending on design requirements. Doped regions may be formed by implantation of dopant atoms, in-situ doped epitaxial growth, and/or other suitable techniques. The substrate 120 may be in wafer form, or the substrate 120 may be illustrative in die form (e.g., after dicing from the wafer).

In an embodiment, a polyimide layer 112 is disposed on the structure 100. The polyimide layer 112 may extend over the seal ring region 104 and the circuit region 102. In an embodiment, the polyimide layer 112 does not extend over the scribe line region 106. In some implementations, the polyimide layer 112 may have a terminal end within the seal ring region 104 for example, in the first seal ring region 104A (e.g., SLDB) or the second seal ring region 104B (e.g., SR). In some embodiments, the polyimide layer 112 may comprise, instead of or in addition to, other suitable compositions such as epoxy, benzocyclobutene (BCB), polybenzoxazole (PBO), or combinations thereof at one or more locations on the structure 100.

Under the polyimide layer 112, a passivation layer 114 comprising a first passivation 114A, a second passivation 114B and a third passivation 114C are provided. The passivation layers 114A, 114B and 114C may comprise a same material. In some implementations, the passivation layers 114A, 114B, and/or 114C comprise silicon nitride. However other dielectric materials are possible. While three passivation layers are shown any number of layers of passivation may be provided between the protective layer 112 and the upper metallization layer of the seal ring structure.

FIG. 1C also illustrates the seal ring structure 116 in cross-sectional view. The seal ring structure 116 includes various layers extending from the substrate and up to the passivation layer 114. In particular, the seal ring structure 116 includes a plurality of conductive vias 116A, a plurality of conductive metal layers 116B between which the vias 116A extend, and interposing dielectric materials 116C. As discussed above, the plurality of vias 116A, metal layers 116B, and dielectric materials 116C are formed in a BEOL process, and may also be referred to as a multi-layer interconnect (MLI).

The conductive lines 116B and vias 116A may each include copper (Cu), titanium nitride (TiN), tungsten (W), ruthenium (Ru), other suitable conductive material, combinations thereof, and/or other suitable conductive materials. The dielectric materials 116C may include interlayer dielectric (ILD) layers having compositions such as tetraethylorthosilicate (TEOS) oxide, un-doped silicate glass, or doped silicon oxide, borophosphosilicate glass (BPSG), fused silica glass (FSG), phosphosilicate glass (PSG), boron doped silicon glass (BSG), silicon oxycarbide, and/or other suitable dielectric materials, deposited by CVD, flowable CVD (FCVD), other suitable method or a combination thereof. FIG. 1C provides for a designation of metal layers (M0-M13) and interposing via layers (V0-V12). However, the number of layers is exemplary only and any number of layers may be included in the seal ring structure 116. In some implementations, the number of layers of the seal ring structure 116 is provided to match the interconnect layers of the IC(s) formed in the circuit region 102.

The seal ring structure 116 has a ring geometry in a top view designed for protection to the circuit devices in the circuit region 102. That is, the seal ring structure 116 includes conductive features (e.g., 116A/116B) forming a continuous structure or wall surrounding the circuit region 102. The seal ring structure 116 includes conductive features (e.g., 116A/116B) forming a continuous structure in the z-direction upwards from the substrate 120, that is a contiguous path of vias 116A and metal lines 116B extend from the substrate 120 to an uppermost metallization layer (e.g., as illustrated M13).

In some implementations, dummy semiconductor structures are formed in the seal ring region 104 (not shown). For example, dummy gate structures, dummy source/drain features, and/or the like may be disposed on the substrate 120 in the seal ring region 104 (e.g., underlying the seal ring structure 116). Additionally, the third region 104C of the seal ring region 104 may include metal and via layers (not shown) coplanar with the portions of the seal ring structure 116. In some implementations, the metal and via layers of the seal ring region 104C may be dummy features.

The semiconductor structure 100 in various embodiments may be formed with other technologies, such as system on chip (SoC), integrated fan out (InFO) packaging technologies, package-on-package (POP), Chip-on-Wafer-on-Substrate (CoWoS), and other suitable structure/technology. For example, in some implementations, redistribution layers coplanar with the sRDL 110 and RV 108 may be disposed in the circuit region 102 to provide interconnection to the devices of the circuit region and an input/output terminal of the structure 100, the I/O depending on the package type.

The sRDL 110 and the RV 108 are disposed on and connected to a first stack 116′ of the seal ring structure 116. The sRDL 110 may be disposed vertically over the first stack 116′ (e.g., aligned over in a z-direction). The sRDL 110 and RV 108 may be physically connected and electrically coupled to the first stack 116′. In an embodiment, a conductive path from the sRDL 110 to a ground of the substrate 120 is provided through the RV 108 and the first stack 116′ of the seal ring structure 116.

As discussed above, the sRDL 110 and the RV 108 are excluded from a corner region of the seal ring region 104. The corner region of the seal ring region 104 includes the seal ring structure 116, and above the seal ring structure 116 lies the passivation layers 114. Thus, in some implementations, the passivation layer 114 interfaces an entirety of an uppermost surface of the seal ring structure 116 disposed at the corner of the seal ring region 104.

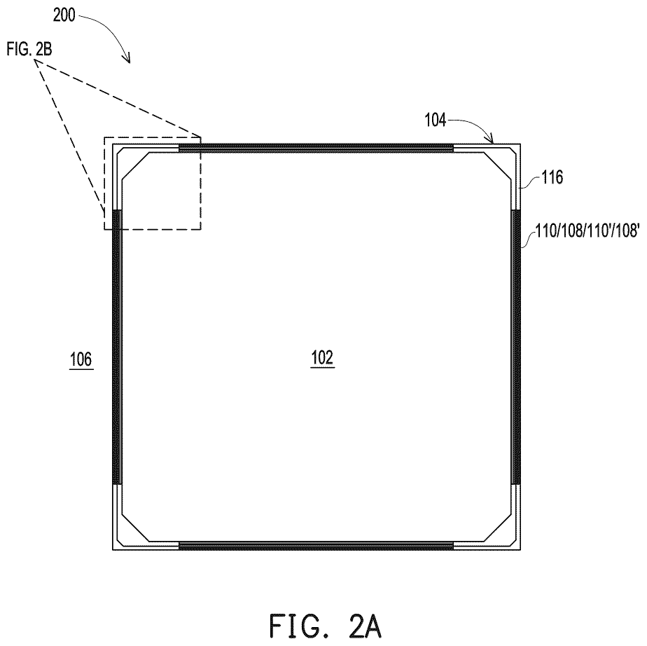

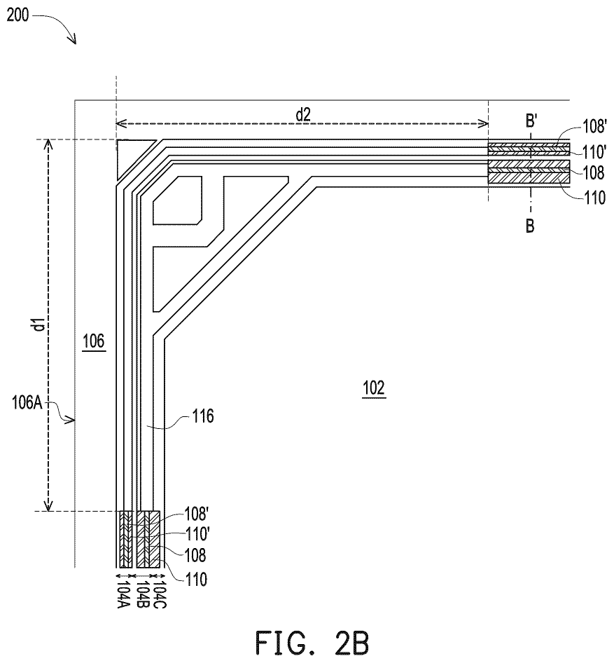

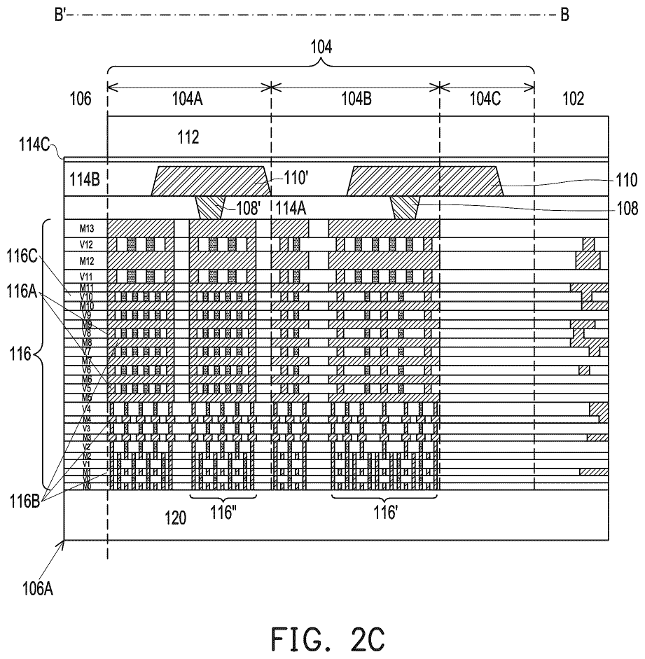

Referring now to FIGS. 2A, 2B, and 2C, illustrated is a semiconductor structure 200 according to aspects of the present disclosure. The semiconductor structure 200 includes many of the same aspects as the semiconductor structure 100, with the differences explained in the following. The semiconductor structure 200 (such as a manufactured wafer or a part thereof) includes a circuit region (or device region) 102 and a seal ring region 104 that encloses the circuit region 102 from a top view. The circuit region 102 may include a plurality of active and/or passive devices. In an embodiment, the circuit region 102 includes at least one transistor. The seal ring region 104, in a top view such as FIG. 2A, is formed as a rectangular structure having four sides meeting at four corner regions similar to as discussed above with reference to FIG. 1A. A seal ring structure 116 in the seal ring region 104 is disposed over a substrate and formed of multiple metal layers stacked thereover and along z-direction as discussed in detail below including with respect to FIG. 2C. FIG. 2B illustrates a top view of an inset of FIG. 2A at a region for case of illustration. The corner region includes a first length d1 and a second length d2. In an embodiment, the first length d1 is between approximately 50 μm and approximately 200 μm. In an embodiment, the first length d1 is at least approximately 50 μm. In an embodiment, the second length d2 is between approximately 50 μm and approximately 200 μm. In an embodiment, the second length d2 is at least approximately 50 μm.

Similar to as discussed above with reference to the structure 100, the seal ring region 104 includes a plurality of subregions that form the seal ring region 104. As illustrated in FIG. 2B, in the structure 200 the seal ring region 104 includes a first region 104A that is a SLDB/SLD region, a second region 104B that is a SR (seal ring wall), and a third region 104C that is a SREZ. The scribe line region 106 similarly is disposed outside of the seal ring region 104.

The seal ring region 104 includes a seal ring structure 116, which is formed encasing the circuit region 102. The seal ring structure 116 provides a continuous metallization feature encircling the circuit region 102 from a top view; and the seal ring structure 116 provides a continuous metallization feature extending upward from the substrate 120 to an upper metallization layer. As illustrated in FIGS. 2A, 2B, 2C, a super redistribution layer (sRDL) 110 and redistribution via (RV) 108 are disposed in the seal ring region 104 and over the seal ring structure 116. In an embodiment, the sRDL 110 and RV 108 are disposed in the second region 104B (e.g., SR) of the seal ring region 104. In an embodiment, the sRDL 110 extends into the third region 104C (e.g., SREZ). In some other embodiments, neither sRDL 110 nor RV 108 are disposed in or extend into the third region 104C (e.g., SREZ). As also illustrated in FIGS. 2A, 2B, 2C, in the structure 200, another super redistribution layer (sRDL) 110′ and another redistribution via (RV) 108′ are disposed in the first region 104A (e.g., SLDB). The RV 108/108′ and the sRDL 110/110′ may include copper. In other embodiments, the RV 108/108′ and the sRDL 110/110′ are other conductive materials such as aluminum, aluminum alloy (such as aluminum/silicon/copper alloy), copper, copper alloy, titanium, titanium nitride, tantalum, tantalum nitride, tungsten, polysilicon, metal silicide, other suitable metals, or a combination thereof.

The sRDL 110, RV 108, sRDL 110′ and RV 108′ are disposed at the lateral sides of the seal ring region 104 from a top view. However, sRDL 110, RV 108, sRDL 110′ and RV 108′ are not disposed in the corner regions of the seal ring region 104. In other words, the corner regions of the seal ring region 104 are devoid of sRDL 110, RV 108, sRDL 110′ and RV 108′. In some implementations, exclusion of the sRDL 110, RV 108, sRDL 110′ and RV 108′ from the corner regions serves to mitigate cracking of the protective layer(s) (e.g., passivation) and/or delamination of protective layers in the corner regions. An exemplary corner region of the seal ring region 104, such as illustrated in FIG. 2B, includes the first length d1 and the second length d2 (e.g., approximately 50 μm and approximately 200 μm) where there is no sRDL component is formed. That is, in a top view, there is a terminal end of the sRDL 110 and sRDL 110′ within the seal ring region 104 along the lateral side. The sRDL 110 and sRDL 110′ as illustrated in the top view of FIGS. 2A/2B are illustrative of a continuous line extending along each side of the seal ring region 104. However, other configurations are possible including as illustrated below. Further, the configuration of sRDL 110 and sRDL 110′ may differ from one another.

FIG. 2C illustrates a cross-sectional view along line B-B′ of the structure 200 of FIG. 2B and provides additional details of the structure 200. FIG. 2C illustrates the substrate 120 on which the circuit region 102, the seal ring region 104, and the scribe line region 106 are disposed. The polyimide layer 112 is disposed on the structure 200 and may be substantially the same as discussed above with reference to the structure 100. Under the polyimide layer 112, a passivation layer 114 comprising a first passivation 114A, a second passivation 114B and a third passivation 114C are provided. The passivation layers 114A, 114B and 114C may comprise a same material. In some implementations, the passivation layers 114A, 114B, and/or 114C comprise silicon nitride. However other dielectric materials are possible.

As discussed above, the seal ring region 104 includes the seal ring structure 116. The seal ring structure 116 includes various metallization layers (metal lines and vias) extending contiguously from the substrate and up to the passivation layer 114, with surrounding dielectric materials. In particular, the seal ring structure 116 includes a plurality of conductive vias 116A, conductive metal layers 116B, and interposing dielectric materials 116C, of an MLI.

The seal ring structure 116 has a ring geometry designed for protection to the circuit devices in the circuit region 102. That is, the seal ring structure 116 includes conductive features (e.g., 116A/116B) forming a continuous structure or wall surrounding the circuit region 102. The seal ring structure 116 includes conductive features (e.g., 116A/116B) forming a continuous structure in the z-direction upwards from the substrate 120, that is a contiguous path of vias 116A and metal lines 116B extend from the substrate 120 to an uppermost metallization layer (e.g., as illustrated M13). The seal ring structure 116 may include several stacks, each stack including connected metallization layers (metal lines and vias), and each stack separated from adjacent stacks. For example, in FIG. 2C four separate stacks are illustrated, though any number are possible. One stack is annotated 116′ and another stack is annotated 116″.

In some implementations, dummy semiconductor structures are formed in the seal ring region 104 (not shown). For example, dummy gate structures, dummy source/drain features, and/or the like may be disposed on the substrate 120 in the seal ring region 104 (e.g., underlying the seal ring structure 116). Additionally, the third region 104C may include metal and via layers coplanar with the portions of the seal ring structure 116 (not shown). In some implementations, the metal and via layers of the seal ring region 104C (metallization not shown) may be dummy features.

The sRDL 110 and the RV 108 are disposed on and connected to the first stack 116′ of the seal ring structure 116. The sRDL 110 may be disposed vertically over the first stack 116′ (e.g., aligned over in a z-direction). The sRDL 110 and RV 108 may be physically connected and electrically coupled to the first stack 116′. In an embodiment, a conductive path from the sRDL 110 to a ground of the substrate 120 is provided through the RV 108 and the first stack 116′ of the seal ring structure 116.

The sRDL 110′ and the RV 108′ are disposed on and connected to a second stack 116″ of the seal ring structure 116. The sRDL 110′ may be disposed vertically over the second stack 116″ (e.g., aligned over in a z-direction). The sRDL 110′ and RV 108′ may be physically connected and electrically coupled to the second stack 116″. In an embodiment, a conductive path from the sRDL 110′ to a ground of the substrate 120 is provided through the RV 108′ and the second stack 116″ of the seal ring structure 116. As illustrated in FIG. 2C, another stack may interpose the first stack 116′ and the second stack 116″ where in some implementations no sRDL or RV are formed connected to the interposing stack.

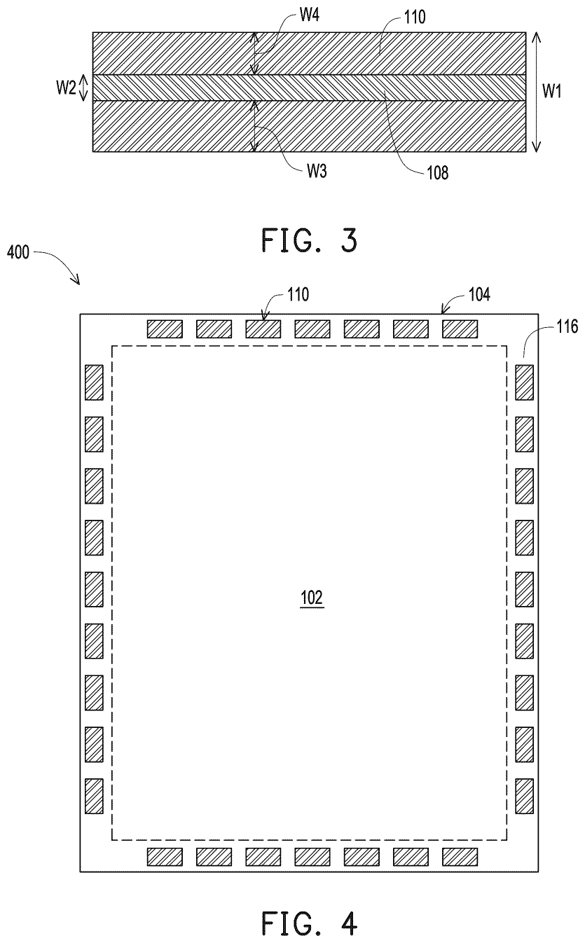

Referring to FIG. 3, illustrated is a top view of a conductive structure illustrating an sRDL 110 feature and RV 108 feature. The conductive structure comprising sRDL 110 and RV 108 may be implemented in the semiconductor structure 100 and/or the semiconductor structure 200 discussed above. In an embodiment, a width of the sRDL 110 is W1. In some implementations, W1 is between approximately 3.6 μm and approximately 10 μm. In an embodiment, a width of the RV 108 is W2. In some implementations, W2 is between approximately 1.8 μm and approximately 2.7 μm. In an embodiment, a distance W3 is between an edge of the RV 108 and a respective edge of the sRDL 110 and a distance W4 is between another edge of the RV 108 and another respective edge of the sRDL 110. In some implementations, W3 and W4 are greater than or equal to approximately 0.45 μm. In some implementations, W3 is approximately equal to W4.

Referring to the example FIG. 4, a top view of a semiconductor structure 400 is illustrated. The semiconductor structure 400 may be substantially similar to the semiconductor structure 100 and/or the semiconductor structure 200 discussed above. Further, the semiconductor structure 400 may include the dimensions of illustrated in FIG. 3. The semiconductor structure 400 includes a seal ring structure 116, which may be substantially similar to as discussed above including with respect to FIGS. 1C and 2C. Over the seal ring structures 116 in the edge portions of the seal ring region 104 of the structure 400 are sRDL features 110. One or more of the sRDL 110 may have a RV 108 connected to and disposed directly below the sRDL 110.

The sRDL 110 of the semiconductor structure 400 are disposed at each lateral side of the seal ring region 104. The sRDL 110 are a non-continuous metal line also referred to as being configured as a plurality of segments. That is, a plurality of separate sRDL 110 are disposed on a given side of the seal ring region 104, with a dielectric such as passivation 114 laterally interposing the segments. Each of the segments of the sRDL 110 may differ in dimensions and shapes from one another including differing configurations of segments disposed on a same lateral side of the structure 400. Any number of segments may be provided for a lateral side of the seal ring region 104. The segments of sRDL 110 may assist to distribute stress for example during the sawing or dicing processes of the die from wafer form. sRDL features 110 are excluded from the corner regions of the seal ring region 104. In some implementations, at least 50 μm of distance from the corner includes seal ring structure 116 but does not include any sRDL feature 110.

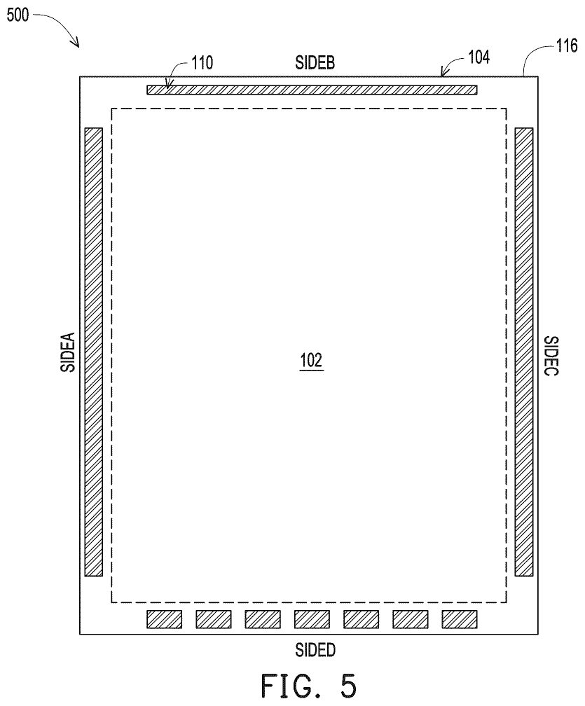

Referring to the example FIG. 5, a top view of a semiconductor structure 500 is illustrated. The semiconductor structure 500 may be substantially similar to the semiconductor structure 100 and the semiconductor structure 200 discussed above. Further, the semiconductor structure 500 may include the dimensions of illustrated in FIG. 3. The semiconductor structure 500 includes a seal ring structures 116, which may be substantially similar to as discussed above including with respect to FIGS. 1C and 2C. Over the seal ring structure 116 in the lateral edge portions of the seal ring region 104 of the structure 400 are sRDL features 110. One or more of the sRDL 110 may have a RV 108 connected to and disposed directly below the sRDL 110. sRDL features 110 are excluded from the corner regions of the seal ring region 104. In some implementations, at least 50 μm of distance from the corner includes seal ring structure 116 but does not include any sRDL feature 110.

The sRDL 110 of the semiconductor structure 500 at SIDEA, SIDEB, SIDEC of the seal ring region 104 are continuous lines from the top view. The sRDL 110 of the semiconductor structure 500 at SIDED of the seal ring region 104 are non-continuous lines or segments from the top view. Any number of segments may be provided on SIDED of the seal ring region 104. The sRDL 110 of each side may differ in dimensions and shapes, including as illustrated by a width variation between SIDEA and SIDEB.

In the illustrated embodiment, SIDEA and SIDEC are symmetrical in that the configuration of the sRDL 110 on each side is equal in shape and size from a top view. In an embodiment, SIDEA and SIDEC are symmetrical in that the configuration of the sRDL 110 on each side is equal in shape and size from a cross-sectional view. In the illustrated embodiment, SIDEB and SIDED are asymmetrical in that the configuration of the sRDL 110 on each of the lateral sides is different. It is noted that the configuration of semiconductor structure 500 is exemplary only and the sides of the seal ring region 104 may have different structures than as illustrated or be provided in a different arrangement. In some implementations, one or more lateral sides may have no SRDL 110.

As with the semiconductor structures 100, 200 and 400, no sRDL 110 features are included in corner regions of the seal ring region 104. In some implementations, approximately 50 μm to 200 μm (e.g., d1 and d2 above) from a corner of the seal ring region 104 is free of sRDL 110 features. Such a configuration may mitigate cracking of layers (e.g., passivation, polyimide), seal ring structure 116, and/or sRDL features 110.

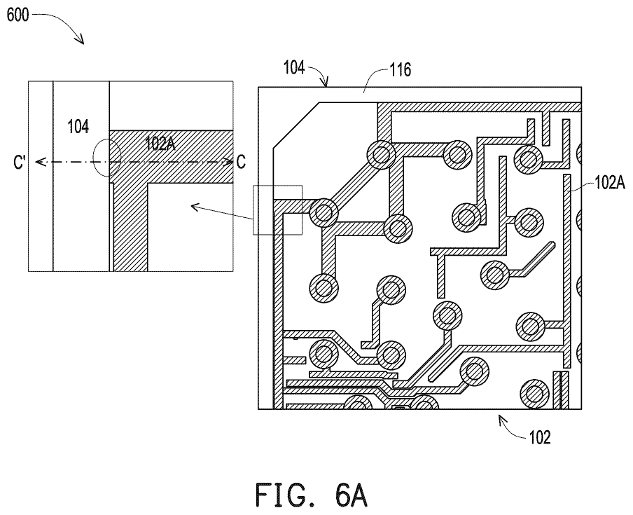

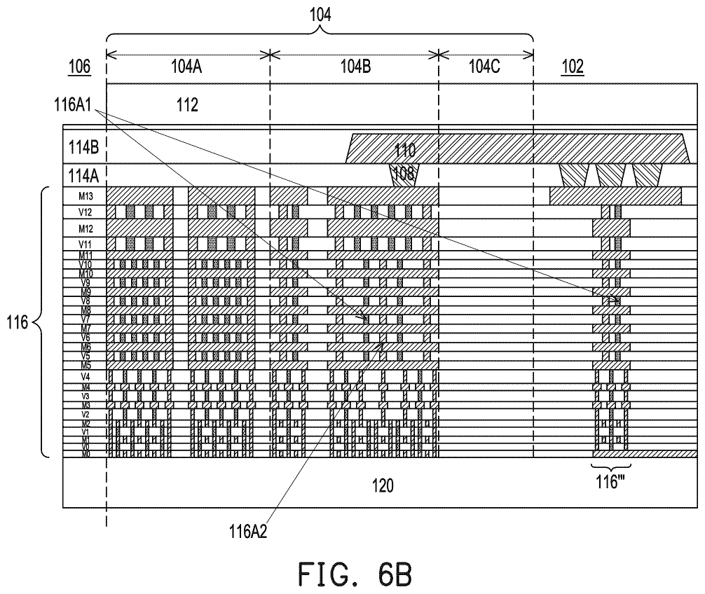

FIGS. 6A and 6B illustrate a semiconductor structure 600 in a top view and cross-sectional view along a cut C-C′ respectively. The semiconductor structure 600 may be substantially similar to the structures 100, 200, 400, and/or 500 discussed above. The semiconductor structure 600 includes a circuit region 102 and a seal ring region 104. FIG. 6A illustrates a top view of a top metal layer 102A of the circuit region 102. The top metal layer 102A may be a copper layer. In other embodiments, the top metal layer 102A includes other conductive materials such as aluminum, aluminum alloy (such as aluminum/silicon/copper alloy), copper, copper alloy, titanium, titanium nitride, tantalum, tantalum nitride, tungsten, polysilicon, metal silicide, tungsten, other suitable metals, or a combination thereof.

The top metal layer 102A may provide a redistribution layer (RDL). The RDL may provide a path for a signal from devices of the circuit region 102 to a conductive feature for input/output connection (e.g., a bond pad). The RDL provided by the top metal layer 102A of the circuit region may be coplanar with the sRDL 110 features of the seal ring region 104. In an embodiment, the RDL of the top metal layer 102A is contiguous with an sRDL 110 of the seal ring region 104. As illustrated in the cross-sectional view of FIG. 6B, a contiguous sRDL 110 extends from the seal ring region 104 (in particular, the second region 104B and the third region 104C) to the circuit region 102. In the circuit region 102, the sRDL 110 may connect to a stack 116′″ of a multi-layer interconnect (MLI) that is coupled to active devices (not shown) disposed on the substrate 120 in the circuit region 102. In some implementations, the sRDL 110 is connected to ground.

As illustrated in FIG. 6B, components of the via layers 116A of the conductive structure 116 include vias 116A1 and vias 116A2. In some implementations, the vias 116A1 are continuous and extend into the page to form a closed structure surrounding the circuit region 102. In some implementations, the features 116A2 are a conductive block (e.g., polygon, circular, in a top view).

As with the semiconductor structures 100, 200, 400, and/or 500, no sRDL 110 features are included in corner regions of the seal ring region 104. In some implementations, approximately 50 μm to 200 μm from a corner of the seal ring region 104 is free of sRDL 110 features. Such a configuration may mitigate cracking of layers (e.g., passivation, polyimide), seal ring structure 116, and/or sRDL features 110.

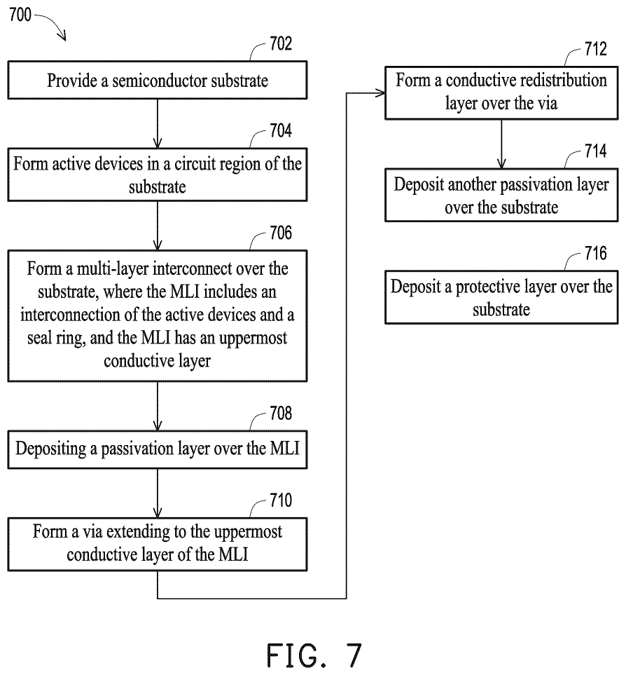

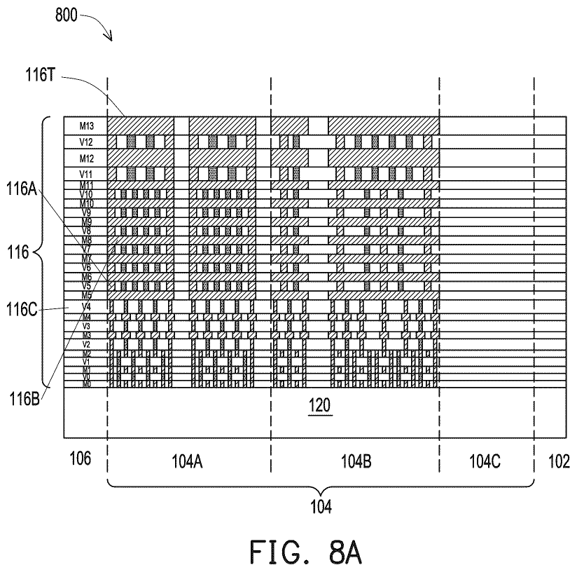

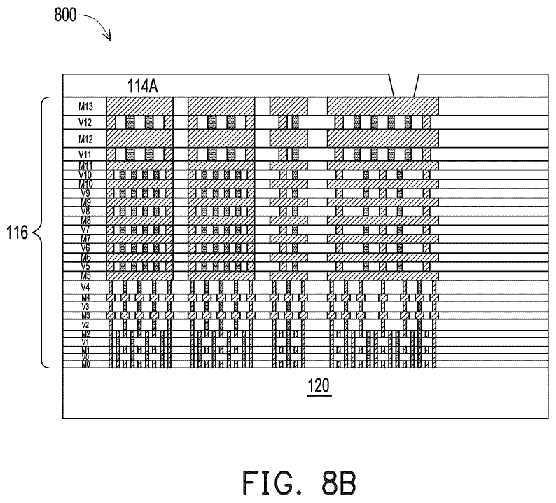

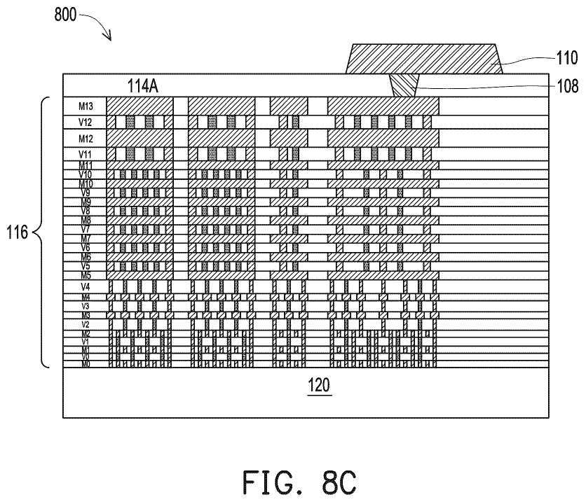

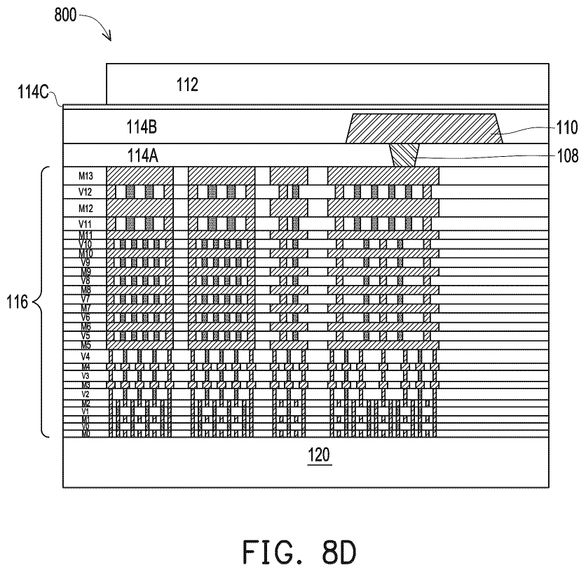

FIG. 7 is a flow chart of a method 700 for fabricating a semiconductor structure, according to various aspects of the present disclosure. FIGS. 8A, 8B, 8C, and 8D are cross-sectional views of a semiconductor structure 800 at various fabrication stages associated with method 700 of FIG. 7 according to various aspects of the present disclosure. The semiconductor structure 800 may be substantially similar to the semiconductor structures 100, 200, 400, 500, and/or 600 discussed above. And the description of the semiconductor structures and the features thereof apply equally to the semiconductor structure 800. To that effect, the method 700 may be used to fabricate any one of the semiconductor structures 100, 200, 400, 500, and/or 600 discussed above.

The method 700 begins at a block 702 where a semiconductor substrate is provided. The semiconductor substrate may be substantially similar to the semiconductor substrate 120, discussed above. Referring to the example of FIG. 8A, a semiconductor substrate 120 is provided for the semiconductor structure 800. The semiconductor substrate 120 may include a circuit region 102, a seal ring region 104, and a scribe line region 106. In an embodiment, the semiconductor substrate is in wafer form a plurality of circuit regions 102, seal ring regions 104, and scribe line regions 106 are formed, at least one region for each die formed on the semiconductor substrate. The seal ring region 104 may include multiple subregions. As illustrated in FIG. 8A, the seal ring region 104 includes a first region 104A that is a SLDB/SLD region, a second region 104B that is a SR (seal ring wall), and a third region 104C that is a SREZ.

The method 700 includes block 704 where active devices are formed in a circuit region of the substrate of block 702. The formation of active devices may also include the formation of corresponding passive devices—the active and passive devices formed in the circuit region may include resistors, capacitors, inductors, diodes, p-type FETs (PFETs), n-type FETs (NFETs), metal-oxide semiconductor FETs (MOSFETs), complementary metal-oxide semiconductor (CMOS) transistors, bipolar junction transistors (BJTs), laterally diffused MOS (LDMOS) transistors, high voltage transistors, high frequency transistors, other components, or a combination thereof. In some implementations, a corresponding dummy device may be formed in a seal ring region of the semiconductor substrate where the corresponding device is similar in features but does not provide electrical functionality to the device (e.g., dummy gate structures provided or pattern uniformity).

The method 700 includes block 706 wherein a multi-layer interconnect (MLI) is formed over the substrate. The MLI may be formed using BEOL fabrication processes. The MLI includes a first portion disposed in the circuit region 102 of the substrate 120, the first portion providing interconnection of the active and passive devices of the circuit region 102. The MLI includes a second portion disposed in the seal region providing a seal ring structure for surrounding the circuit region 102.

Referring to the example if FIG. 8A, an MLI structure is formed in the seal ring region 104, which is illustrated as seal ring structure 116. The seal ring structure 116 includes conductive lines 116B and conductive vias 116A that together form a contiguous structure extending from the substrate 120 to an upper metal layer 116T. The seal ring structure 116 surrounds the circuit region 102. The seal ring structure 116 may be substantially similar to as discussed above.

The method 700 includes block 706 where a passivation layer is deposited over the substrate. Referring to the example of FIG. 8B, a first passivation layer 114A is formed. The passivation layer 114A may be deposited by suitable deposition process such as chemical vapor deposition (CVD). In an embodiment, the first passivation layer may include a silicon nitride layer. In some implementations, the first passivation layer 114A may be a multiple layer structure such as a SiCN and an overlying SiN layer. After deposition, a chemical mechanical polish (CMP) process may be performed. In some embodiments, as illustrated in FIG. 8B, the first passivation layer 114A may be patterned through suitable photolithography and etch processes to form an opening in the passivation layer 114A. In subsequent processing as discussed below, a via may be formed in the opening.

The method 700 includes block 710 where a via extending to the uppermost layer of the MLI is formed. In particular, a conductive via extends to the uppermost layer of MLI in the seal ring region; that is, the upper layer of the seal ring structure. Referring to the example of FIG. 8C, a via 108 is formed in the opening in the passivation layer 114A. The via 108 may be substantially similar to the RV 108 discussed above. The via 108 may be formed by depositing conductive material such as copper within the opening of the passivation layer 114A. The via 108 may include conductive material such as copper (Cu) aluminum (Al), aluminum copper alloy (AlCu), gold, titanium, cobalt, an alloy, or another conductive material. In some embodiments, the vias are formed through, for example, electrochemical plating (ECP), electroplating, electroless plating, chemical vapor deposition, atomic layer deposition, or another process. In an embodiment, the formation of the via 108 may include depositing a liner or seed layer, and then filling the opening to form the via 108. In some implementations, the via 108 is formed concurrently with the RDL layer 110 of block 712.

The method 700 includes block 712 where a redistribution layer (RDL) is formed over the via. Referring to the example of FIG. 8C, a redistribution layer 110 is formed over the passivation layer 114A and the via 108. The redistribution layer 110 may be substantially similar to the sRDL 110 discussed above. The redistribution layer 110 may be formed by depositing conductive material such as copper over the passivation layer 114A and patterning the deposited conductive material through suitable photolithography and etch processes. The redistribution layer 110 may include conductive material such as copper (Cu) aluminum (Al), aluminum copper alloy (AlCu), gold, titanium, cobalt, an alloy, or another conductive material. In some embodiments, the vias are formed through, for example, electrochemical plating (ECP), electroplating, electroless plating, chemical vapor deposition, atomic layer deposition, or another process. In an embodiment, the formation of the redistribution layer 110 may include depositing a liner or seed layer.

As with the semiconductor structures 100, 200, 400, 500, and/or 600, no RDL features are included in corner regions of the seal ring region. In some implementations, approximately 50 μm to 200 μm or at least 50 μm from a corner of the seal ring region is free of redistribution features. Such a configuration may mitigate cracking of layers (e.g., passivation, polyimide), seal ring structure, and/or redistribution layers.

The method 700 continues to block 714 where additional passivation layers are formed. Referring to the example of FIG. 8D, passivation layers 114B and 114C are formed including over the RDL 110. The passivation layers 114C and 114C may comprise a dielectric material, such as undoped silicate glass (USG), silicon nitride, silicon oxide, silicon oxynitride or a non-porous material by any suitable method, such as CVD, PVD, or the like. In an implementation, after deposition of the insulating material, a chemical mechanical polish (CMP) process is performed.

The method 700 continues to block 716 where additional protection layers are formed. Referring to the example of FIG. 8D, polyimide layer 112 is formed over the passivation layers 114A, 114B, 114C. The polyimide layer 112 may comprise polyimide (PI) or other suitable compositions such as epoxy, benzocyclobutene (BCB), or polybenzoxazole (PBO) and may be deposited by spin on coating or other suitable deposition methods. In some implementations, the method 700 may continue to perform dicing process to separate the semiconductor structure 800 into separate die.

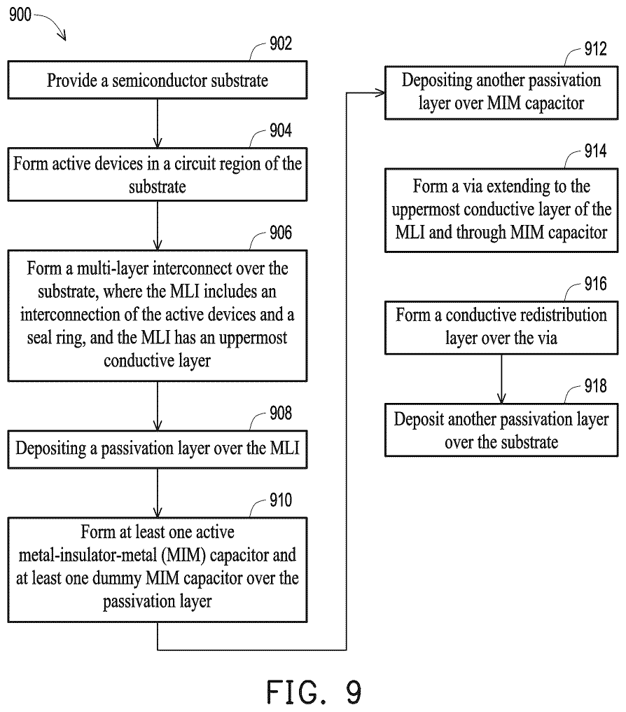

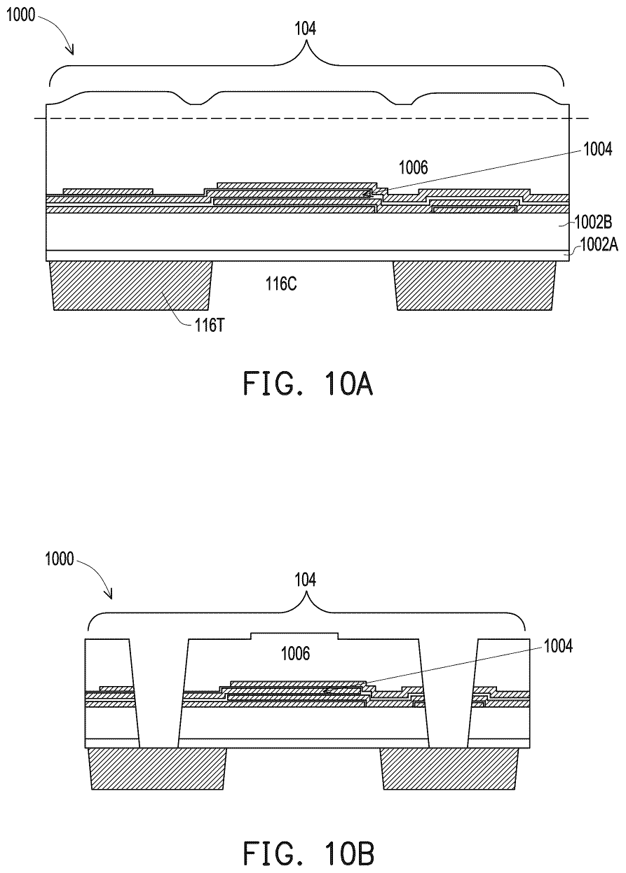

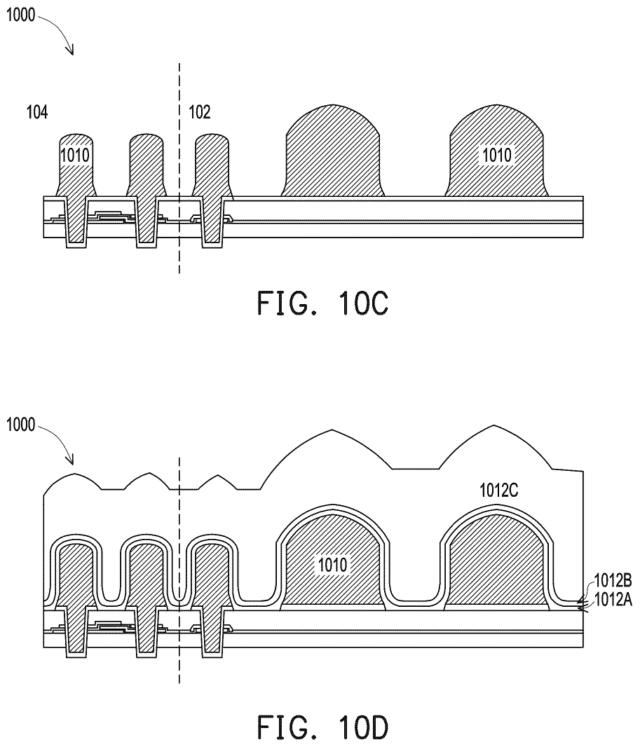

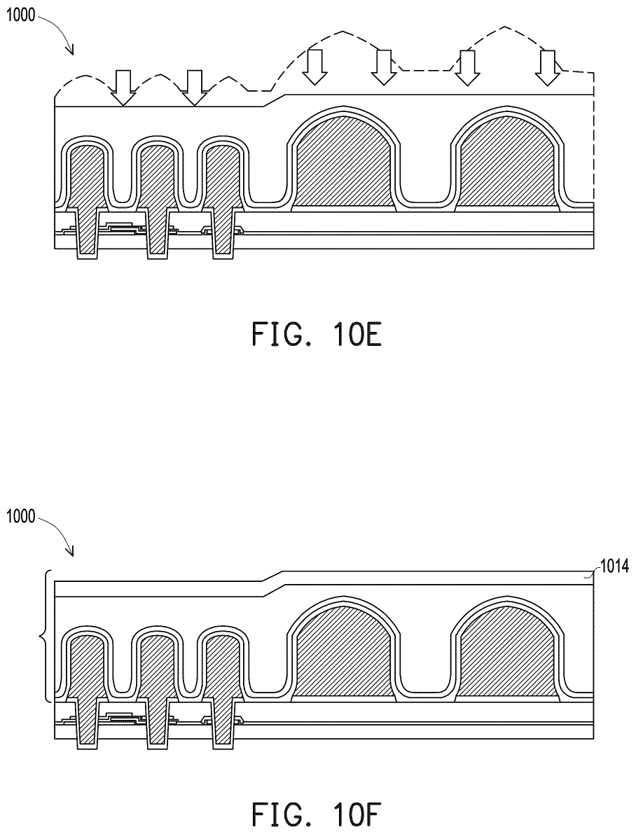

FIG. 9 is a flow chart of a method 900 for fabricating a semiconductor structure, according to various aspects of the present disclosure. FIGS. 10A, 10B, 10C, 10D, 10E, and 10F are cross-sectional views of a semiconductor structure 1000 at various fabrication stages associated with method 900 of FIG. 9 according to various aspects of the present disclosure. The semiconductor structure 1000 may be substantially similar to the semiconductor structures 100, 200, 400, 500, 600, and/or 800 discussed above. And the description of the semiconductor structures and the features thereof apply equally to the semiconductor structure 1000. To that effect, the method 900 may be used in conduction with the method 700 and/or any one of the semiconductor structures 100, 200, 400, 500, 600, and/or 800. In some implementations, the redistribution layer, discussed with respect to block 916 (and the via discussed with respect to block 914) may be excluded from a corner region of a seal region of the device such that no redistribution layer is formed extending into said corner region (e.g., 50 μm from a corner of the chip).

The method 900 begins at a block 902 where a semiconductor substrate is provided. Block 902 may be substantially similar to block 702 of the method 700 and the provided semiconductor substrate may be substantially similar to the semiconductor substrate 120, discussed above. The method 700 also includes block 904 where active devices are formed in a circuit region of the substrate of block 902. Block 904 may be substantially similar to block 704 of the method 700 discussed above. The method 700 further includes block 906 where wherein a multi-layer interconnect (MLI) is formed over the substrate. Block 906 may be substantially similar to block 706 of the method 700. As discussed above, the MLI forms an interconnect in the circuit region 102 of the substrate and a seal ring structure 116 in the seal ring region 104 of the substrate. The MLI includes a top or uppermost layer 116T, illustrated in FIG. 10A.

The method 900 includes block 908 where a passivation layer is deposited. Block 908 may be substantially similar to block 708 of the method 700. Referring to the example of FIG. 10A, a passivation layer 1002 including passivation layer 1002A and 1002B is formed. The passivation layer 1002 may be deposited by suitable deposition process such as chemical vapor deposition (CVD). In an embodiment, the first passivation layer 1002A may include a silicon carbon nitride layer. In some implementations, a thickness of the passivation layer 1002A may be between approximately 1 Angstrom and approximately 3 Angstroms. In an embodiment, the second passivation layer 1002B may include a silicon nitride layer. In some implementations, a thickness of the passivation layer 1002B may be between approximately 4000 Angstrom and approximately 8000 Angstroms. After deposition, a chemical mechanical polish (CMP) process may be performed.

The method 900 includes block 910 where at least one active metal-insulator-metal (MIM) capacitor and at least one dummy MIM capacitor are formed over the passivation layer. In an embodiment, the dummy MIM capacitor is formed in the seal ring region 104. In an embodiment, at least one active MIM capacitor is formed in the circuit region 102. Active MIM capacitors are used to store a charge in a variety of semiconductor devices. A MIM capacitor may be formed horizontally on a semiconductor wafer, with two metal plates sandwiching a dielectric layer. As illustrated in FIG. 10A, a plurality of metal and interposing dielectric layers form a MIM capacitor 1004. The illustrated MIM capacitor 1004 is a dummy structure and formed in the seal ring region 104. In some instances, the MIM capacitor 1004 as a dummy structure in the seal ring region 104 is formed to provide more uniform pattern density when forming active MIM capacitors in a circuit region 102.

The method 900 includes block 912 where another passivation layer is formed over the MIM capacitor(s). The deposition of the passivation layer may be substantially similar to block 714 of the method 700 discussed with reference to FIG. 7. Referring to the example of FIG. 10A, a passivation layer 1006 is formed. The passivation layer 1006 may be deposited by suitable deposition process such as chemical vapor deposition (CVD). In an embodiment, the passivation layer 1006 may include a silicon nitride layer. In some implementations, a thickness of the passivation layer 1006 may be between approximately 8000 Angstroms and approximately 15000 Angstroms. After deposition, a chemical mechanical polish (CMP) process may be performed. See the dashed line in FIG. 10A.

The method 900 includes block 914 where a via is formed extending to the uppermost layer of the MLI that forms the seal ring structure. In some embodiments, as illustrated in FIG. 10B, the first passivation layer 1002A/1002B and the second passivation layer 1006 may be patterned through suitable photolithography and etch processes to form an opening extending to the top surface of the upper metallization 116T and through the MIM capacitor 1004. In particular, the via opening extends to expose the uppermost layer of MLI in the seal ring region 104; that is, the via formed extends to contact the upper layer of the seal ring structure. Referring to the example of FIG. 10C, a via 1008 is formed in the opening. The via 108 may be substantially similar to the RV 108 discussed above. The via 1008 may be formed by depositing conductive material such as copper within the opening of FIG. 10B. The via 1008 may include conductive material such as copper (Cu) aluminum (Al), aluminum copper alloy (AlCu), gold, titanium, cobalt, an alloy, or another conductive material. In some embodiments, the vias are formed through, for example, electrochemical plating (ECP), electroplating, electroless plating, chemical vapor deposition, atomic layer deposition, or another process. In an embodiment, the formation of the via 1008 may include depositing a liner or seed layer, and then filling the opening to form the via 1008. In some implementations, the via 1008 is formed concurrently with the RDL layer 110 of block 916.

The method 900 includes block 916 where a redistribution layer (RDL) is formed over the via. Referring to the example of FIG. 10C, a redistribution layer 1010 is formed over the passivation layer 1006 and the via 1008. The redistribution layer 1010 may be substantially similar to the sRDL 110 discussed above. The redistribution layer 1010 may be formed by depositing conductive material such as copper over the passivation layer 1006 and patterning the deposited conductive material. The redistribution layer 1010 may include conductive material such as copper (Cu) aluminum (Al), aluminum copper alloy (AlCu), gold, titanium, cobalt, an alloy, or another conductive material. In some embodiments, the vias are formed through, for example, electrochemical plating (ECP), electroplating, electroless plating, chemical vapor deposition, atomic layer deposition, or another process. In an embodiment, the formation of the redistribution layer 1010 may include depositing a liner or seed layer. The redistribution layer 1010 in the seal ring region 104 may be formed concurrently with the redistribution layer of the circuit region 102. As discussed above, the redistribution layer 1010 is patterned such that it is excluded from a corner region of the seal ring region 104 in a top view.

The method 900 continues to block 918 where additional passivation layers and/or dielectric protective layers are formed. Referring to the example of FIGS. 10D-10F, passivation layers 1012A, 1012B, 1012C are formed including over the RDL 1010. In an embodiment, layer 1012A is a dielectric layer such as silicon nitride. An exemplary thickness for the layer 1012A is between approximately 1000 Angstroms and 2000 Angstroms. In an embodiment, layer 1012A is a dielectric layer such as undoped silicon oxide. An exemplary thickness for the layer 1012A is between approximately 1000 Angstroms and 3000 Angstroms. In an embodiment, layer 1012C is a dielectric layer such as HDP deposited oxide. An exemplary thickness for the layer 1012C is between approximately 20k Angstroms and 40k Angstroms. The passivation layers may alternatively comprise other suitable dielectric materials, such as undoped silicate glass (USG), silicon nitride, silicon oxide, silicon oxynitride or a non-porous material by any suitable method, such as CVD, PVD, HDP, or the like. In an implementation, after deposition of the insulating material, a chemical mechanical polish (CMP) process is performed as illustrated in FIG. 10E. An additional passivation layer 1014 may be formed as illustrated in FIG. 10F. In an embodiment, the additional passivation layer 1014 may be silicon oxide. In some implementations, the layer 1014 may have a thickness between approximately 5k Angstroms and 10k Angstroms. The method may proceed to further steps including, for example, providing additional protection layers such as a polyimide, epoxy, benzocyclobutene (BCB), or polybenzoxazole (PBO) layer deposited by spin on coating or other suitable deposition methods.

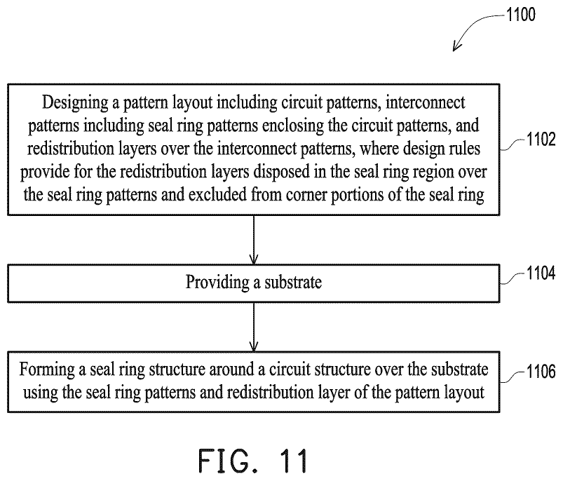

FIG. 11 is a flow chart of a method 1100 for designing and fabricating a semiconductor structure, according to various aspects of the present disclosure. The method 1100 may be implemented to form any one of semiconductor structures 100, 200, 400, 500, 600, 800, and 1000 discussed above.

The method 1100 includes a block 1102 where a pattern layout is designed. The pattern layout includes circuit patterns, interconnect patterns including seal ring patterns enclosing the circuit patterns, and redistribution layers over the interconnect patterns, where the redistribution layers are disposed in the seal ring region over the seal ring patterns exclusive of the corner portions of the seal ring region. The pattern layout is a physical design layout, which is typically produced using computer aided design tools. The layout may include definition of active features (e.g., transistors including gates, doped regions), isolation regions, interconnect structures (including conductive lines, vias and contacts of an MLI), and/or other physical elements that will be formed on a substrate. The layout typically includes a plurality of “layers” that correspond to each of a plurality of “layers” to be fabricated on a substrate (e.g., a semiconductor wafer) to form an integrated circuit. A typical format for the layout is a GDS II file, however other formats are possible.

The layout may be formed according to design rules. The design rules may be defined and provided in the computer aided design (CAD) tools used to form the layouts. In an embodiment, the design rules dictate requirements of the layout and a design rule checker (DRC) is performed to ensure each layout conforms to said rules. In an embodiment, the design rules include restrictions on providing a redistribution layer in certain areas of the seal ring region of a chip. In particular, the design rules may preclude placing a pattern including the redistribution layer in a corner region of the seal region of the chip (i.e., adjacent a corner of the circuit region). In an embodiment, the design rules may preclude placing a pattern including the redistribution layer in a corner region of the seal region of the chip within a distance of d1 or d2 from the corner of a chip (e.g., 50 microns to 200 microns). In some implementations, the design rules preclude placing a pattern including the redistribution layer in a corner region of the seal region of the chip within a distance of at least 50 microns of the corner.

The method 1100 then proceeds to block 1104 where a semiconductor substrate is provided. And in block 1106 through a plurality of fabrication steps including those of the method 700, discussed above with reference to FIG. 7, or the method 900, discussed above with reference to FIG. 9, a semiconductor structure is fabricated. The semiconductor structure includes features defined by the pattern layout. To that effect, the block 1104 includes forming, according to the layout, a seal ring structure around a circuit region of the substrate using the seal ring patterns and forming a redistribution layer over the seal ring structure exclusive of the corner regions of the seal ring.

Although not intended to be limiting, some embodiments of the present disclosure provide one or more of the following advantages. For example, embodiments of the present disclosure provide a seal ring region enclosing a circuit region. Redistribution layers may be formed over and connected to the seal ring structure of the seal ring region. In some implementations, the redistribution layers (and underlying stack of seal ring structure) are connected to ground. The redistribution layers of the seal ring region may be disposed along the edges of the seal ring region but excluded from corner regions of the seal ring region such that the seal ring region at the corner region is devoid of the redistribution layer. The omission of the redistribution layers in the corner regions may provide for a decreased risk of delamination, cracking, or other defects of features of the seal ring region. This reduction risk provides an increased protection of the circuit features from processing (e.g., dicing/sawing) and environmental effects.

In one example aspect, the present disclosure is directed to a semiconductor structure including a substrate having a circuit region and a seal ring region around the circuit region and at least one stack of a multi-layer interconnect (MLI) extending from the substrate to an upper metallization layer in the seal ring region. The at least one stack is continuous around the circuit region in a top view. The structure further includes a redistribution layer disposed over the upper metallization layer. The redistribution layer extends along a lateral side of the seal ring region and a corner of the seal ring region is devoid of the redistribution layer.

In a further embodiment, the structure also includes at least one transistor formed in the circuit region and another stack of the MLI disposed over and connected to the at least one transistor. In an embodiment, the seal ring region is substantially rectangular shape in a top view. The redistribution layer is disposed on a first side of the substantially rectangular shape and a second side of the substantially rectangular shape, the corner disposed between the first side and the second side. In an embodiment, a corner devoid of the redistribution layer has a first length extending to the first side. The corner devoid of the redistribution layer has a second length extending to the second side. And the first and second lengths are at least 50 microns. In an embodiment, the redistribution layer is disposed on a first side of the substantially rectangular shape and a second side of the substantially rectangular shape, the first side opposing the second side in the top view. In some implementations, the redistribution layer on the first side is a plurality of segments in the top view and the redistribution layer on the second side is a continuous line in the top view. The continuous line may be longer than the plurality of segments. In an embodiment, the structure also includes a protection layer over the redistribution layer.

In another of the broader embodiments, a semiconductor structure includes a substrate having a circuit region and a seal ring structure comprising a plurality of metallization layers. The seal ring structure surrounds the circuit region in a top view such that the seal ring structure is disposed along a first side of the circuit region, a second side of the circuit region and a corner of the circuit region between the first side and the second side. A first element of a redistribution layer is disposed over the seal ring structure disposed along the first side of the circuit region and a second element of the redistribution layer is disposed over the seal ring structure disposed along the second side of the circuit region. No element of the redistribution layer is disposed over the seal ring structure disposed along the corner of the circuit region.

In a further embodiment, the structure also includes a via extending from the first element of the redistribution layer to an uppermost metallization layer of the seal ring structure. In an implementation, a passivation layer is formed adjacent the via and adjacent the redistribution layer. In an embodiment, a passivation layer interfaces an entirety of an uppermost surface of the seal ring structure disposed at the corner of the circuit region. And in some examples, the first element of the redistribution layer and the second element of the redistribution layer are asymmetrical.

In a method of the present disclosure, a semiconductor substrate having a circuit region and a seal ring region is provided. An active device is formed in the circuit region. A multi-layer interconnect (MLI) is formed over the semiconductor substrate, a first stack of the MLI forming an interconnection to the active device and a second stack of the MLI forming a seal ring structure surrounding the active device region. After forming the MLI, a passivation layer is deposited over the MLI. A redistribution layer is formed over the passivation layer. The forming the redistribution layer includes depositing a conductive material; and patterning the conductive material such that it is disposed only at a lateral side of the seal ring region. A protective layer is formed over the redistribution layer.

In an embodiment of the method, the method also includes designing a pattern layout including defining circuit patterns for the circuit region; interconnect patterns providing the first stack in the circuit region and the second stack in the seal ring region; and redistribution layers for the circuit region and the seal ring region, wherein the pattern layout for the redistribution layers excludes the redistribution layer from corner portions the seal ring area. In an implementation, designing the pattern layer includes implementing a design rule to exclude the redistribution layer from corner portions the seal ring area. In a further embodiment, the design rule excludes at least 50 microns of length adjacent the corner from including the redistribution layer. In an embodiment, in forming the MLI a stack of conductive vias are formed alternating between conductive lines, and dielectric materials are deposited around the stack. In an embodiment, depositing the protective layer includes spin coating a polyimide.

The foregoing outlines features of several embodiments so that those of ordinary skill in the art may better understand the aspects of the present disclosure. Those of ordinary skill in the art should appreciate that they may readily use the present disclosure as a basis for designing or modifying other processes and structures for carrying out the same purposes and/or achieving the same advantages of the embodiments introduced herein. Those of ordinary skill in the art should also realize that such equivalent constructions do not depart from the spirit and scope of the present disclosure, and that they may make various changes, substitutions, and alterations herein without departing from the spirit and scope of the present disclosure.

What is claimed is:

1. A method of fabricating a semiconductor structure, comprising:
providing a semiconductor substrate having a circuit region and a seal ring region;
forming an active device in the circuit region;
forming a multi-layer interconnect (MLI) connected to the active device in the circuit region and a seal ring;
depositing a first passivation layer over the MLI;
forming at least one active metal-insulator-metal (MIM) capacitor and at least one dummy MIM capacitor over the first passivation layer;
depositing a second passivation layer over the at least one active MIM capacitor and at least one dummy MIM capacitor; and
forming a via through the first passivation layer and the second passivation layer and extending to an uppermost conductive layer of the MLI and through the MIM capacitor.

2. The method of claim 1, further comprising:
forming a conductive redistribution layer over the via; and
depositing a third passivation layer over the conductive redistribution layer.

3. The method of claim 2, wherein the conductive redistribution layer is connected to the seal ring.

4. The method of claim 1, wherein the depositing the first passivation layer includes forming a silicon carbon nitride layer.

5. The method of claim 4, wherein the depositing the second passivation layer includes forming a silicon nitride layer.

6. The method of claim 1, further comprising:
performing a chemical mechanical polish (CMP) process after the second passive layer and prior to forming the via.

7. The method of claim 1, wherein the forming the at least one dummy MIM capacitor over the first passivation layer forms the at least one dummy MIM capacitor over the seal ring.

8. The method of claim 1, wherein the forming the via includes forming the via on a first side of the at least one dummy MIM capacitor and forming a second via on a second side of the at least one dummy MIM capacitor in a cross-sectional view.

9. A method of fabricating a semiconductor structure comprising:
providing a semiconductor substrate having a circuit region and a seal ring region surrounding the circuit region in a top view;
forming a multi-layer interconnect (MLI), wherein the MLI is connected to an active device in the circuit region forms a seal ring in the seal ring region;
depositing a first passivation layer over the MLI;
forming at least one dummy metal-insulator-metal (MIM) capacitor over the first passivation layer;
depositing a second passivation layer over the at least one active MIM capacitor and at least one dummy MIM capacitor; and
forming a redistribution layer over the second passivation layer, wherein the forming the redistribution layer includes:
depositing conductive material; and
patterning the conductive material to form the redistribution layer connected to the seal ring and an active device in the circuit region.

10. The method of claim 9, further comprising:
forming a third passivation layer over the redistribution layer.

11. The method of claim 10, wherein the forming the third passivation layer includes:
forming a first dielectric layer, a second dielectric layer, and a third dielectric layer.

12. The method of claim 11, wherein the first dielectric layer is undoped silicon oxide.

13. The method of claim 10, further comprising:
after the forming the third passivation layer, performing a chemical mechanical planarization (CMP) process to form a surface.

14. The method of claim 13, further comprising:
forming an additional passivation layer on the surface.

15. The method of claim 10, further comprising:
forming a via extending between the redistribution layer and the MLI.

16. The method of claim 15, wherein the forming the via includes:
forming the via extending through the third passivation layer.

17. A method of semiconductor device fabrication comprising:
providing design rules associated with a pattern layout;
designing the pattern layout, wherein the designing the pattern layout includes:
defining circuit patterns and interconnect patterns including seal ring patterns enclosing the circuit patterns, and
defining redistribution layers over the interconnect patterns, where the redistribution layers are disposed in the seal ring region over the seal ring patterns exclusive of a corner of the seal ring region;
enforcing a design rule of the design rules prohibiting a redistribution layer in the corner of the seal ring region during the defining the circuit patterns;
providing a substrate; and
forming the pattern layout including the redistribution layer on the substrate.

18. The method of claim 17, wherein the design rule prohibits the redistribution layer between a distance d1 and a distance d2 from the corner.

19. The method of claim 18, wherein d1 is approximately 50 microns and d2 is approximately 200 microns.

20. The method of claim 17, wherein the design rule prohibits the redistribution layer within a distance of at least 50 microns from the corner.
